(19) United States
(12) Patent Application Publication
(10) Pub. No.: US 2026/0316180 A1
(43) Pub. Date: Oct. 15, 2026

(54) METHOD FOR DETERMINING THE WELDING DEPTH IN A LASER WELDING PROCESS

(71) Applicant: TRUMPF Laser SE, Schramberg (DE)

(72) Inventors: Jakob Von Essen, Schramberg (DE); Jan-Patrick Hermani, Markgröningen (DE)

(21) Appl. No.: 19/655,737

(22) Filed: Apr. 23, 2026

Related U.S. Application Data
(63) Continuation of application No. PCT/EP2024/080208, filed on Oct. 25, 2024.

(30) Foreign Application Priority Data
Oct. 26, 2023 (DE) 10 2023 129 521.7

(51) Int. Cl. B23K 26/03; B23K 26/384; G01B 9/02091; G01B 11/06; G01B 11/22

(52) U.S. Cl. CPC B23K 26/032; B23K 26/384; G01B 9/02091; G01B 11/0608; G01B 11/22

(57) ABSTRACT

A method for determining a welding depth in a laser welding process by using an optical coherence tomography apparatus includes directing a processing laser beam onto a component to produce a keyhole, coupling a measurement beam into a beam path of the processing laser beam, performing line scans over the component using the measurement beam in a region of the keyhole, capturing light portions that are reflected off the component, generating a height profile of the component in the region of the keyhole, based on the height profile, determining a height of a component surface of a lateral position of a deepest point of the keyhole and a depth of the deepest point of the keyhole, determining a keyhole depth from a difference between the height of the component surface and the depth of the deepest point of the keyhole, and ascertaining the welding depth from the keyhole depth.

### CROSS REFERENCE TO RELATED APPLICATIONS

This application is a continuation of International Application No. PCT/EP2024/080208 (WO 2025/088106 A1), filed on Oct. 25, 2024, and claims benefit to German Patent Application No. DE 10 2023 129 521.7, filed on Oct. 26, 2023. The aforementioned applications are hereby incorporated by reference herein.

### FIELD

Embodiments of the present invention relate to a method for determining the welding depth in a laser welding process by means of an optical coherence tomography apparatus.

### BACKGROUND

In laser welding processes using a processing laser beam, measuring the welding depth is essential to guarantee a high-quality weld seam. If the welding depth is not sufficient, the weld seam will not have the required strength. However, excessive welding depth can lead to penetration welds. Therefore, various methods have already been proposed to measure the welding depth in laser welding processes.

When using an optical coherence tomography apparatus to measure the welding depth, correct measuring positioning of the measurement beam is essential. The measurement beam must be positioned on the deepest point of the keyhole of the component generated by the processing laser beam in order to reliably measure the welding depth. Since the deepest position of the keyhole can change depending on the process parameters, a setup process must be carried out before the laser welding process to determine the measuring position for the measurement beam. However, the known setup processes are complex and require a second measuring step to determine the welding depth.

For example, in the method known from DE 10 2017 117 413 B4, the measuring position of the measurement beam for measuring the welding depth is determined by carrying out a plurality of scans with the measurement beam in the feed direction of the processing laser beam and perpendicular thereto, in order to be able to create a height profile of the component in the region of the keyhole generated by the processing laser beam from these scans by means of an optical coherence tomography apparatus. The lateral position of the deepest point of the keyhole can be determined from the height profile. The measurement beam is then directed at the deepest point of the keyhole and the actual measurement of the welding depth is carried out.

A similar method for determining the measuring position of a measurement beam is also known from DE 10 2019 103 734 A1.

DE 10 2016 005021 A1 describes a method by which the welding depth during a laser processing process can be measured by directing the measurement beam to the deepest point of a keyhole and measurements of the depth of the deepest point are carried out at several different points in time, the welding penetration depth being determined from the data of these different measurements given a known height position of the component surface.

### SUMMARY

Embodiments of the present invention provide a method for determining a welding depth in a laser welding process by using an optical coherence tomography apparatus. The method includes directing a processing laser beam onto a component to produce a keyhole, coupling a measurement beam into a beam path of the processing laser beam, performing a plurality of line scans over the component using the measurement beam in a region of the keyhole, capturing light portions of the measurement beam that are reflected off the component using the optical coherence tomography apparatus, generating a height profile of the component in the region of the keyhole from the plurality of line scans, based on the height profile, determining a height of a component surface of a lateral position of a deepest point of the keyhole on the component and a depth of the deepest point of the keyhole, determining a keyhole depth from a difference between the height of the component surface and the depth of the deepest point of the keyhole, and ascertaining the welding depth from the keyhole depth.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a cross-section through a component in the region of a keyhole generated by a processing laser beam according to some embodiments;

FIG. 2 shows a distribution of measurement data from a plurality of OCT scans over the region of the keyhole of the component from FIG. 1, according to some embodiments;

FIGS. 3a and 3b show the creation of a height profile of two keyholes from measurement data of a plurality of OCT scans according to some embodiments; and

FIGS. 4a and 4b show histogram evaluations of measurement data of the depth of two keyholes according to some embodiments.

### DETAILED DESCRIPTION

Embodiments of the present invention provide a more rational method for measuring the welding depth in laser processing operations.

directing a processing laser beam onto a component, which generates a keyhole therein;

coupling a measurement beam into the beam path of the processing laser beam;

carrying out a plurality of line scans over the component using the measurement beam in the region of the keyhole and capturing the light portions of the measurement beam that are reflected off the component using the optical coherence tomography apparatus, and generating a height profile of the component in the region of the keyhole from the line scans;

from the height profile, determining the height of the component surface of the lateral position of the deepest point of the keyhole on the component and also the depth of the deepest point of the keyhole;

calculating the keyhole depth from the difference between the height of the component surface and the depth of the deepest point of the keyhole, and ascertaining the welding depth therefrom.

In the method according to embodiments of the invention, all parameters necessary for determining the welding depth are recorded from the measurement data of the plurality of scans carried out with the measurement beam at different points in time and at different spatial positions. From these measurement data and the resulting height profile of the component in the region of the keyhole, the height of the component surface, the lateral position of the deepest point of the keyhole, and the depth of the keyhole at this point can be determined. The welding depth can then be calculated from this depth and the height of the component surface. In contrast to known methods, this method does not require two separate measurements, namely, a first measurement to determine the lateral position of the deepest point of the keyhole and a second measurement, after directing the measurement beam to the deepest point of the keyhole, to determine the depth of the keyhole at that point.

The line scans can preferably be carried out with the measurement beam in the feed direction of the processing laser beam and/or transversely thereto. This allows the entire region of the keyhole as well as the component surface not melted by the processing laser beam to be captured with the scans.

Further advantages arise when the measurement data of a plurality of or all scans carried out with the measurement beam is superimposed, and a height profile of the component in the region of the keyhole is generated by forming a sliding intensity-weighted average from the measurement data, and the lateral position of the deepest point of the keyhole is ascertained.

Similarly, the measurement data of a plurality of or all scans carried out with the measurement beam can be superimposed, and a height profile of the component in the region of the keyhole is generated by forming a sliding intensity-weighted average from the measurement data, and the height of the component surface can be ascertained.

From the height profile determined by this averaging, the height of the component surface and/or the lateral position of the deepest point of the keyhole can thus be determined with sufficient accuracy. The depth of the keyhole at its deepest point can also be determined from the height profile.

However, a higher accuracy in the depth measurement of the steam capillary can be achieved if the measurement data generated by the scans with the measurement beam in the region of the deepest point of the keyhole are filtered by means of a percentile filter with a sliding temporal process window or by means of a histogram evaluation in order to determine the depth of the keyhole at its deepest point, and, therefrom, the welding depth.

In a histogram evaluation of the measurement data, a statistically significant histogram class, in particular the one having the greatest number of measurement points lying below the height position of the component surface, can directly indicate the welding depth.

The method according to embodiments of the invention can be carried out to set up a laser processing machine prior to a production process and/or continuously or at time intervals during the production process.

If the method is only used to set up a production process, the average welding depth is already known with the setup. Subsequently, for ongoing monitoring of the welding depth, after carrying out the method for setting up a laser processing machine, the measurement beam can be directed towards the lateral position of the deepest point of the keyhole, and the depth of the keyhole at its deepest point can be continuously measured and the welding depth calculated therefrom. In this case, the method is used solely for the rational setup of the laser processing machine prior to the production process. Subsequently, a continuous measurement of the welding depth is carried out by holding the measurement beam above the deepest point of the keyhole at the measuring position determined during the setup of the laser processing machine. This use of the method may be sufficient when producing weld seams with consistent parameters. Preferably, however, the inventive method is also carried out again during the production process, either continuously or at temporal or spatial intervals, in order to compensate for any shifts in the deepest point of the keyhole and still be able to correctly determine the welding depth. This is particularly important in continuous welding processes such as pipe welding.

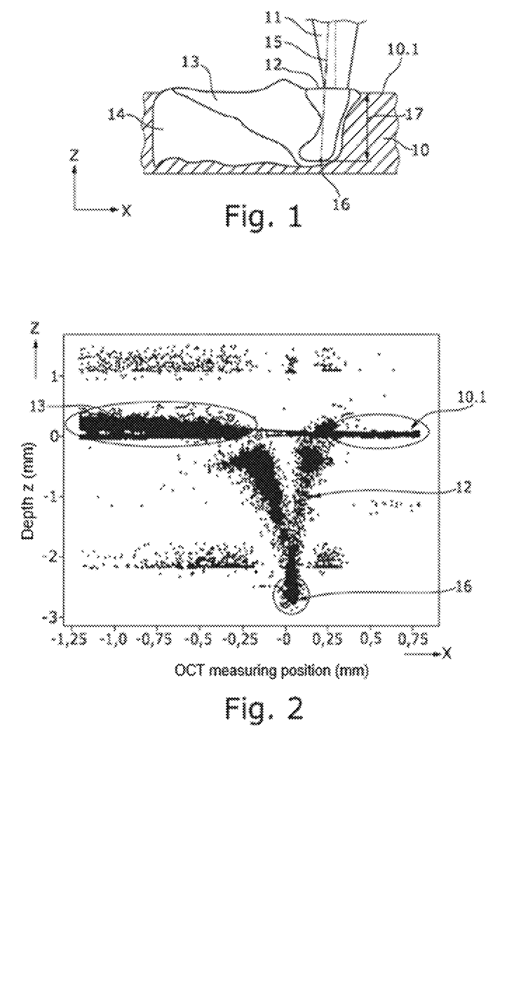

FIG. 1 illustrates the production of a weld seam 14 in a component 10. For this purpose, the component 10 is irradiated by a processing laser beam 11. The processing laser beam 11 creates a keyhole 12 in the component 10, in which the material of the component 10 is in a gaseous or plasma-like state. The processing laser beam 11 moves in direction x over the component 10. Therefore, a weld pool 13 forms behind the keyhole, in which the previously gaseous material of the component 10 in the keyhole 12 has already transitioned into a liquid state through cooling. Further away from the keyhole 12, a weld seam 14 forms in which the material of the component 10 has already solidified.

To measure the welding depth 17 of the weld seam 14, a measurement beam 15 of an optical coherence tomography apparatus OCT (not shown) is directed at the deepest point 16 of the keyhole 12 and the depth of the keyhole 12 in the z-direction at this point 16 is determined from the reflected radiation. The distance of this measured depth from the surface 10.1 of the component 10 corresponds to the welding depth 17 of the weld seam 14.

FIG. 2 illustrates how, according to a method according to embodiments of the invention, a multitude of depth measurement points in the z-direction are generated by lateral scans with the measurement beam 15 over a component, such as the component 10 from FIG. 1, above a measurement line extending in the feed direction x of the processing laser beam 11. The measuring points are created by reflections of the measurement beam 11 at the component surface 10.1, the keyhole 12 and the weld pool 13.

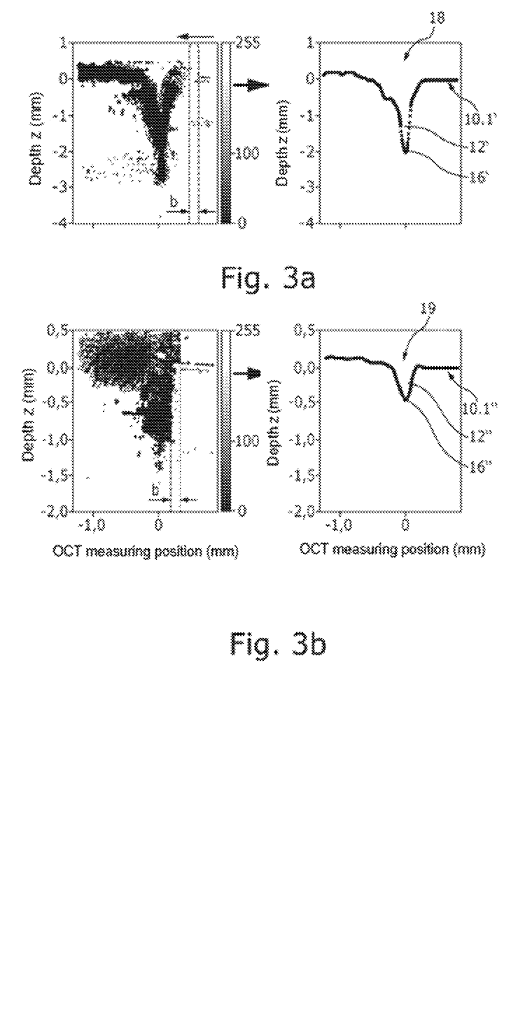

From this multitude of measurement points, a height profile 18, 19 of the scanned component is created according to the two examples in FIGS. 3a, 3b by forming a sliding intensity-weighted average from the measurement data. For this purpose, a window M of length b is moved along the measurement line formed by the positions of the measurement beam (OCT measuring positions) in the x-direction and the average is calculated from all measurement data contained in this window. From the resulting height profiles 18, 19, the lateral position of the deepest point 16‘, 16“ of the height profiles 18, 19 can be determined.

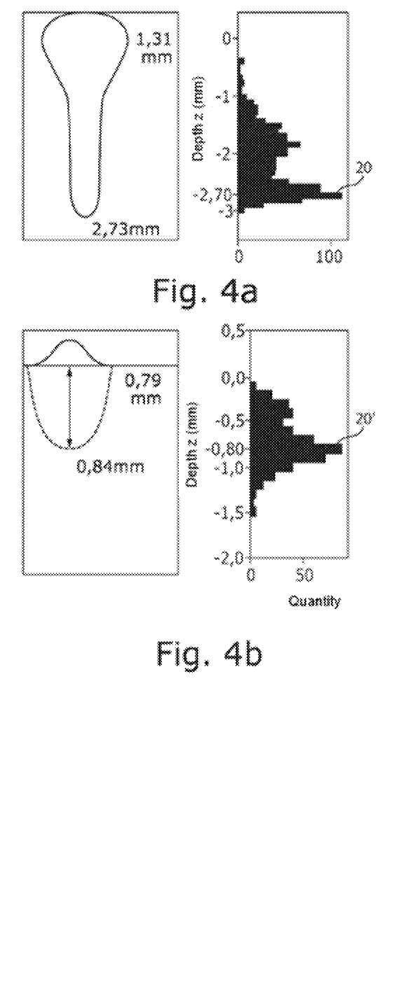

Subsequently, the measurement data near these deepest points 16‘, 16“ can be evaluated by histograms to determine the depth of the keyhole 12‘, 12“ as illustrated in FIGS. 4a, 3b. The histogram class 20, 20‘ with the highest number of measurement points that lie below the height position of the component surface 10.1‘, 10.1“ indicates the desired welding depth 17. The height position of the component surfaces 10.1‘, 10.1“ can be determined from the height profiles 18, 19. In the examples shown, the welding depth 17 is 2.70 mm in FIG. 4a and .80 mm in FIG. 4b.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for determining a welding depth in a laser welding process by using an optical coherence tomography apparatus, the method comprising:
directing a processing laser beam onto a component to produce a keyhole;
coupling a measurement beam into a beam path of the processing laser beam;
performing a plurality of line scans over the component using the measurement beam in a region of the keyhole, capturing light portions of the measurement beam that are reflected off the component using the optical coherence tomography apparatus, and generating a height profile of the component in the region of the keyhole from the plurality of line scans;
based on the height profile, determining a height of a component surface of a lateral position of a deepest point of the keyhole on the component and a depth of the deepest point of the keyhole; and
determining a keyhole depth from a difference between the height of the component surface and the depth of the deepest point of the keyhole, and ascertaining the welding depth from the keyhole depth.

2. The method according to claim 1, wherein the plurality of line scans is performed with the measurement beam in a feed direction of the processing laser beam and/or transversely thereto.

3. The method according to claim 1, further comprising superimposing measurement data of the plurality of scans performed with the measurement beam, wherein the height profile of the component in the region of the keyhole is generated by forming a sliding intensity-weighted average from the measurement data, and wherein the lateral position of the deepest point of the keyhole is ascertained from the height profile.

4. The method according to claim 3, wherein the measurement data of the plurality of scans performed with the measurement beam are superimposed, the height profile of the component in the region of the keyhole is generated by forming the sliding intensity-weighted average from the measurement data, and the height of the component surface is ascertained in an image evaluation unit.

5. The method according to claim 3, wherein the measurement data generated by the plurality of scans with the measurement beam in a region of the deepest point of the keyhole are filtered by a percentile filter with a sliding temporal process window or by a histogram evaluation in order to determine the depth of the deepest point of the keyhole and the welding depth.

6. The method according to claim 5, wherein, in the histogram evaluation of the measurement data, a statistically significant histogram class having a greatest number of measurement points lying below a height position of the component surface indicates the welding depth.

7. The method according to claim 1, wherein the method is carried out for setting up a laser processing machine prior to a production process and/or continuously or at time intervals during the production process.

8. The method according to claim 1, wherein, after carrying out the method for setting up a laser processing machine prior to a production process, the measurement beam is directed at the deepest point of the keyhole, the depth of the deepest point of the keyhole is continuously measured, and the welding depth is calculated therefrom.
